(19) United States
(12) Patent Application Publication
(10) Pub. No.: US 2012/0279844 A1
(43) Pub. Date: Nov. 8, 2012

(54) Multifunctional Touch Switch Apparatus for Bathroom

(76) Inventor: David Wang, New Taipei (TW)

(21) Appl. No.: 13/100,194

(22) Filed: May 3, 2011

(51) Int. Cl. H03K 17/98

(52) U.S. Cl. 200/600

(57) ABSTRACT

A multifunctional touch switch apparatus for bathroom, comprising of: mutually fitted upper and lower shells, on the upper shell is a protruding button area with several touch switches and a display screen, the protruding button area locked with the a concave space in the lower shell; a panel closely attached to the upper shell and fastened; a transparent light guide plate closely attached to the panel surface and fastened; a rectangular hollow framework embedded in the center of transparent light guide plate and panel, for fastening the light guide plate; a circuit embedded in the space between upper shell and lower shell, composed of touch-control switch circuit and colorful LED backlight lamp for touch control and colorful backlight changes. Therefore, an innovative multifunctional touch switch apparatus for bathroom is designed for controlling on/off of functions in the bathroom, with LED indicator and colorful backlight color control.

### BACKGROUND OF INVENTION

1. Field of the Present Invention

The present invention relates generally to a multifunctional switch apparatus for bathroom with improved structure and better functionalities, and more particularly to a multifunctional touch switch apparatus for bathroom which controls on/off by touch and with a colorful LED backlight color control.

2. Description of Related Art

Switch apparatus is used for electrical appliances in houses. On the wall mount switches for turning on or of lamps for illumination or household appliances. With the progress of science and technology, the switch of bathroom lamps with the function of ventilation has been invented to provide more human-oriented and convenient utility. Through setting of this bathroom switch, the user may turn on the lamp and ventilation synchronously, so as to achieve the effect of ventilation and deodorization.

The present invention provides a touch switch apparatus for bathroom which makes improvements based on previous bathroom switch:
1. Previous bathroom switches in common use turn on or off lamps and ventilation of fan at the same time, which cannot be used independently; considering inconvenience of ventilation with lamp and deodorization on, energy saving cannot be achieved. In recent architectural design, although the lamp and fan ventilation cannot be used separately, people often turn on the fan and forget turning off it, hence a waste of electrical energy, causing disturbance and inconvenience.
2. For commonly used bathroom switch, button stands out much of the panel due to spacing between panel and button. And the buttons have square angles which might scratch or scrape hands by accident. Most of users' hands become wet after entering or while leaving the bathroom, so once their hands touch the switch, the accident of electric shock might occur.
3. The panel and button for bathroom switch in common use often have a stiff shape, projecting and without shape design, which is incompatible with newly decorated house and not pleasing to eye, in addition, as technology continuously innovates, the object of following trend and fashion will replace monotonous, stiff and changeless appearance and structure of switch.

Accordingly, there are disadvantages of commonly used bathroom switch, which are the objects for technicians familiar with this field to be solved. In view of this, the inventor of the present invention proposes a “multifunctional touch switch apparatus for bathroom” for the purpose of benefiting the public.

### SUMMARY OF THE PRESENT INVENTION

The primary objective of the present invention to provide a multifunctional touch switch apparatus for bathroom that selects the required function by touch control operations. The delay times of each function are different but can be set at will, to facilitate the convenience in use, achieving the effect of convenient life.

The second objective of the present invention is to provide a multifunctional touch switch apparatus for bathroom that decreases the number of components by touch switch designed with modularized electronic components for assembly. No matter how many groups of touch switches on the panel, other components have the same size, thus highly exchangeable, reducing cost and being economically efficient.

It is yet another object to provide a multifunctional touch switch apparatus for bathroom that can reduce dirt, is easy for cleaning and avoid the accident of electrical shock by the integrated design of panel and touch switches.

It is a further object to provide a multifunctional touch switch apparatus for bathroom that saves space and attains the beautification efficacy of indoor decoration with good-looking appearance and sense of fashion by beautiful shape design and diversified color-flashing backlight effect.

In order to realize the objects and effects, a multifunctional touch switch apparatus for bathroom is designed, comprising of:

upper shell and lower shell, on the upper shell is a protruding button area with several touch switches and a display screen, the protruding button area locked with the a concave space in the lower shell; a panel closely attached to the upper shell and fastened; a transparent light guide plate closely attached to the panel surface and fastened; a rectangular hollow framework embedded in the center of transparent light guide plate and panel, for fastening the light guide plate; a circuit embedded in the space between upper shell and lower shell, composed of touch-control switch circuit, colorful LED backlight lamp, for touch control and colorful backlight changes.

The present invention relates to a multifunctional touch switch apparatus for bathroom in which several touch switches represent the following functions: shower, ventilation, toileting and washing hands. The time for each function is not the same. By preset delay time, the user can turn on it after selecting a function, keep electric lights and ventilation on at the preset time and automatically shut down them after the time ends. Therefore, not only the effect of ventilation and deodorization is achieved, but also the requirements for environmental protection and energy saving are met.

The device of the present invention uses several perforations around the button area for colorful LED backlight lamp to form backlight effect while the light ray perforates.

The device of the present invention uses capacitor type, resistance type or infrared touch control circuit.

The present invention relates to a multifunctional touch switch apparatus for bathroom in which the colorful LED backlight lamp has the function of colorful backlight changes, controlled by chips in the circuit structure. The lamp colors contain RGB64-order colors which can be automatically changed.

The present invention relates to a multifunctional touch switch apparatus for bathroom in which the colorful LED indicator lamp keeps shining to provide the backlight effect of the switch apparatus, chip controlled. The moment user touches the switch, it will automatically change the color.

The accompanying drawings illustrate preferred embodiments of the present invention, and, together with the description, serve to explain the principles of the present invention.

### DETAILED DESCRIPTION OF THE PRESENT INVENTION

FIG. 1 is an external view of the preferred embodiment of the multifunctional touch switch apparatus. It is a multifunctional touch switch apparatus for bathroom 1, with a touch switch 10.

FIG. 2 and FIG. 3 are exploded view and partial enlarged section view of the multifunctional touch switch apparatus. The time switch 1 is composed of: mutually-matched upper shell and lower shell 10, 11; a panel 20, tumbled in the upper shell 10; a transparent light guide plate 30, closely attached to the panel 20 surface and fastened; and a circuit 40, embedded in the space between upper shell and lower shell 10, 11. Here:

The upper shell 10 is a rectangular flat plate with protruding button area 101 in the center. A shallow groove 102 divides the button area 101 for several touch switches 103 and a display screen 104. The touch switches 103 are further for the purposes of: shower, ventilation, toileting and washing hands, each of which need different time. By the preset delay time, user may touch it to turn on after selecting the function, so as to control electric lamps and ventilation on at the preset time and automatically off afterwards. Meanwhile, the use state will be displayed on the display screen 104 where the symbols for functions and figures visible to the user at a sight for clearly judging the set action time. Also, there are several perforations 105 around the button area 101 for the colored LED backlight lamp to form the backlight effect while shining. On the concave of the button area 101 there are pairs of tumbling grooves 106 at both sides for joining the lower shell 11; a concave space 111 on the lower shell 11 which has wiring hole area 112 and pairs of tenons 113 at both sides for embedding the corresponding tumbling grooves 106 of the upper shell 10.

The panel 20 is a plate of certain thickness, which can be attached to the upper shell 10, with an allowable button area 101 fitted hollow groove 21. Along the hollow groove 21 there are several protrusions on the surface with a teethed grasp bar 22 of a length. At the outside (the direction far from the hollow groove of the grasp bar 22 has grooves 23 of the same length to join with the rectangular hollow frame 24 in the button area. On a face of the frame 24 also have several protrusions on the surface with a composite convex bar 241 of a length, which composes a high convex bar and a low convex bar with a gap between them. When the frame 24 joins with the panel 20, the high convex bar of the composite convex bar 241 may be tumbled into the grooves 23 and the low convex bar is close to the teethed face of the teethed grasp bar 22, the top of which is tumbled into the gap between high and low convex bars 241. Several protruding points 211 on a proper place around the hollow groove 21, perforating the holes 107 around the button area 101 to clasp it for ensuring the firmly joining of panel 20 and upper shell 10, not easily peeled off and separated.

The transparent light guide plate 30 is transparent sheet material of a certain thickness, closely attached to panel 20 and fastened. There is a groove 31 in the center of the light guide plate 30 for perforating of allowable button area 101, by which the light guide plate 30 is attached to panel 20 through frame 24 joining with panel 20, thus achieving the effect of clasping and fastening the transparent light guide plate 30.

The circuit 40 (not shown on the pictures is stuck into the space between upper shell and lower shell 10, 11, including: a touch switch circuit corresponding; to said button area 101, which can be capacitor type, resistance type or infrared touch control and whose principles of work are hand touching by user, controlling disconnection or connection of electric current by the touch controlled switch circuit sensing the current, resistance or infrared shielding changes, so as to control on/off of electric lamps. When finger touches the touch switches 103 in the button area 101, the inside touch control circuit detects variations of current, resistance or infrared, shielding changes, for controlling turning on of electric lamp and ventilation of any function of the multifunctional switch apparatus for bathroom. A colorful LED backlight lamps has the function of colorful backlight changes, which is controlled by chips in the circuit 40. The lamp colors include RGB64 color changes. The color will automatically change when user touches any switches 103 in the button area 101.

Said colorful LED indicator lamp keeps shining to provide the backlight effect of the time switch 1. The moment user touches the switch 103, it will automatically change the color. The colored lights will shine out of perforations on the button area 101 to the transparent light guide plate 30 for uniformly illuminating, achieving colorful and varying backlight effect.

For the multifunctional touch switch apparatus for bathroom 1 assembled as above, the actual wiring is shown in FIG. 4, which is easy and free for technicians familiar with this technology.

As shown in FIG. 5, while using the multifunctional touch switch apparatus for bathroom 1, user only needs to select the function, touch the corresponding switch 103 in the button area by finger, and then the electric light and ventilation are turned on and will be automatically off at the preset delay time. Meanwhile, the colorful LED backlight lamp will shine and change color each time user touches any switch 103 in the button area 101, changing color alternately according to the preset 64-order colors.

FIG. 6 depicts another diagram of the multifunctional touch switch apparatus for bathroom. The touch switches 103 of the present invention, in addition to the aforesaid vertical design, a transverse design is also acceptable to meet user's diversified needs and further match with indoor decoration, so as to add to the beauty and exhibit unique personal style.

The present invention mainly transforms common bathroom switch to be touch controlled operation, with set time for different functions. It not only accords with scientific and technological progress trend and human-oriented use, but also achieves the double effects of convenient life and improving life utility. For manufacturing, the touch switch design with modularized electronic components reduces the number of components for the sake of assembly, effectively reducing cost and economically efficient. On the other hand, the unique integrated design of panel and touch switch reduces dirt, easily cleaned and prevents accidental electric shock, with higher safety performance. Meanwhile, beautiful appearance can select vertical or transverse shape design, saving space and beautifying indoor decoration, together with automatically changed or manually controlled the backlight effect of 64-order diversified color changes, beautiful and fashionable.

As stated above, the multifunctional touch switch apparatus of the present invention achieves anticipated objects and functions, being a practical and advanced switch apparatus better than switch in common use. It is clear that no products on the market are like the present invention, which conforms to the requirements for patent application and thus being claimed.

Although the present invention has been explained in relation its preferred embodiment, it is to be understood that many other possible modifications and variations can be made without departing from the spirit and scope of the present invention as hereinafter claimed.

### BRIEF DESCRIPTION OF THE DRAWINGS

FIG. 1 is an external view of the multifunctional touch switch apparatus for bathroom of the preferred embodiment.

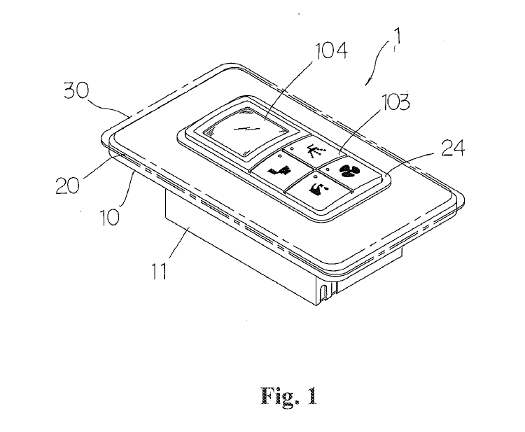

FIG. 2 is an exploded view of the multifunctional touch switch apparatus for bathroom of the preferred embodiment.

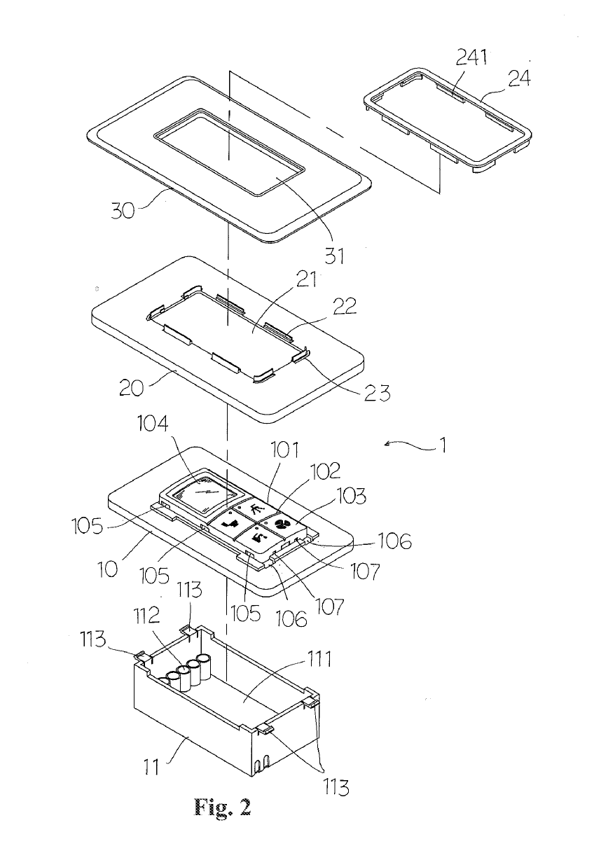

FIG. 3 is a section view and partial enlarged view of the multifunctional touch switch apparatus for bathroom of the preferred embodiment.

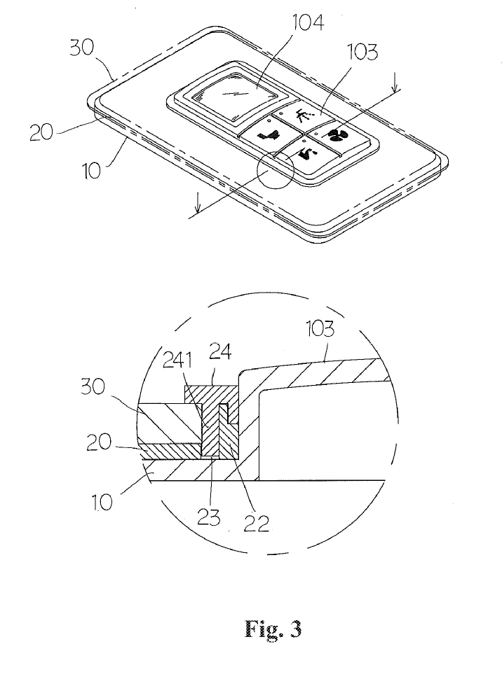

FIG. 4 is a wiring diagram of the multifunctional touch switch apparatus for bathroom of the preferred embodiment.

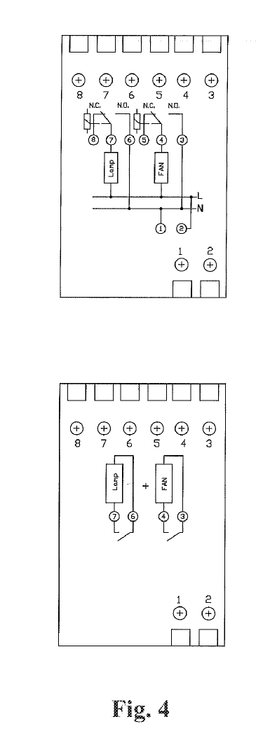

FIG. 5 is a use state diagram of the multifunctional touch switch apparatus for bathroom of the preferred embodiment.

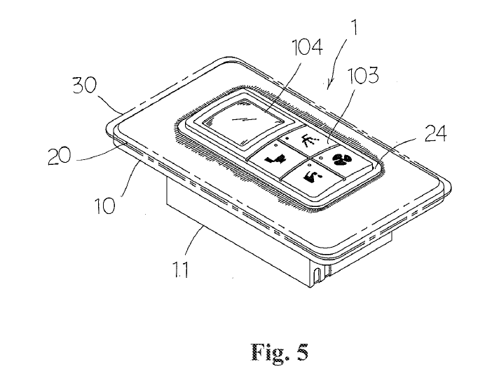

FIG. 6 depicts an appearance diagram of the multifunctional touch switch apparatus for bathroom of another preferred embodiment of the present invention.

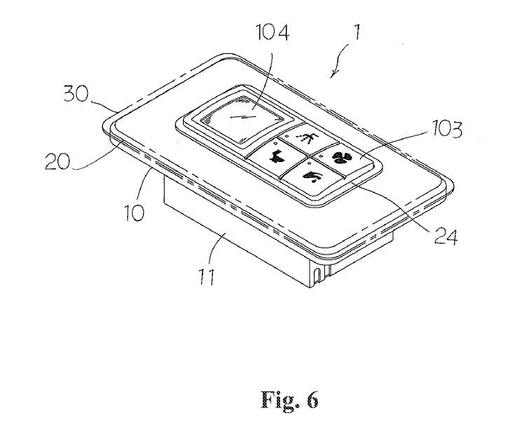

1. A multifunctional touch switch apparatus for bathroom comprises of:
upper shell and lower shell, the upper shell is a rectangular flat plate with protruding button area divided into several touch switches and a display screen, several perforations around the button area, a concave space on the lower shell which can tumble in upper shell;
a panel, closely attached to upper shell, with a protruding hollow groove fit with the allowable button area in the center;
a light guide plate, closed attached to panel, with a groove in the center for perforating of allowable button area;
a rectangular hollow frame, embedded around the groove in the center of the light guide plate, clasping around panel grooves, thus clasping and fastening the transparent light guide plate; and
the circuit is stuck into the space between upper shell and lower shell, including a touch switch circuit and colorful LED backlight lamp for touch control and colorful backlight changes.

2. The multifunctional touch switch apparatus for bathroom as claimed in claim 1, wherein several touch switches represent the functions: shower, ventilation, toileting and washing hands, each of which may preset a delay time. User touches it to turn on after selecting the function, so as to control electric lamps and ventilation on at the preset time and automatically off afterwards.

3. The multifunctional touch switch apparatus for bathroom as claimed in claim 1, wherein the switch may set the action time for different functions and clearly read the set action time through the symbols for functions and figures visible on the display screen.

4. The multifunctional touch switch apparatus for bathroom as claimed in claim 1, wherein action indicator lamps in the button area clearly indicate the action mode after executing the set action, and know the remaining action time through the symbols for functions and figures visible on the display screen.

5. The multifunctional touch switch apparatus for bathroom as claimed in claim 1, wherein perforations around the button area to provide backlight effect for colorful LED backlight lamps shining light rays.

6. The multifunctional touch switch apparatus for bathroom as claimed in claim 1, wherein pairs of tumbling grooves at both sides in the concave of button area of upper shell, and the lower shell has pairs of tenons at both sides for tumbling into the corresponding tumbling grooves.

7. The multifunctional touch switch apparatus for bathroom as claimed in claim 1, wherein the panel has several protrusions on the surface with a teethed grasp bar of a length along the hollow groove. At the outside of the grasp bar there are grooves of the same length. On a face of the frame also have several protrusions on the surface with a composite convex bar of a length, which composes a high convex bar and a low convex bar with a gap between them. When the frame joins with the panel, the high convex bar of the composite convex bar may be tumbled into the grooves and the low convex bar is close to the teethed face of the teethed grasp bar, the top of which is tumbled into the gap between high and low convex bars.

8. The multifunctional touch switch apparatus for bathroom as claimed in claim 1, wherein several protruding points on a proper place around the hollow groove of the panel, perforating the holes around the button area to clasp it for ensuring the firmly joining.

9. The multifunctional touch switch apparatus for bathroom as claimed in claim 1, wherein the touch control switch circuit can be capacitor type, resistance type or infrared touch control.

10. The multifunctional touch switch apparatus for bathroom as claimed in claim 1, wherein the colorful LED backlight lamp has the function of colorful backlight changes, controlled by chips in the circuit structure. The lamp colors contain RGB64-order colors which can be automatically changed or changed while operating functional buttons.

11. The multifunctional touch switch apparatus for bathroom as claimed in claim 1, wherein the colorful LED indicator lamp keeps shining to provide the backlight effect of the multifunctional touch switch apparatus for bathroom, chip controlled. Each time user touches the switch, it will automatically change the color.
